(19) United States
(12) Patent Application Publication
(10) Pub. No.: US 2015/0097486 A1
(43) Pub. Date: Apr. 9, 2015

(54) MULTIZONE HOLLOW CATHODE DISCHARGE SYSTEM WITH COAXIAL AND AZIMUTHAL SYMMETRY AND WITH CONSISTENT CENTRAL TRIGGER

(71) Applicant: Applied Materials, Inc., Santa Clara, CA (US)

(72) Inventors: Andrew NGUYEN, San Jose, CA (US); Kartik RAMASWAMY, San Jose, CA (US); Yogananda SARODE VISHWANATH, Bangalore (IN); Alexander Charles MARCACCI, San Jose, CA (US)

(21) Appl. No.: 14/505,065

(22) Filed: Oct. 2, 2014

Related U.S. Application Data
(60) Provisional application No. 61/888,995, filed on Oct. 9, 2013.

(51) Int. Cl. H01L 21/67; H01J 7/46

(52) U.S. Cl. CPC H01L 21/67069; H01J 7/46
USPC 315/111.21; 239/548; 156/345.34

(57) ABSTRACT

A showerhead assembly includes a front plate having a front surface, a back surface and a plurality of first through holes connecting the front surface and the back surface, a back plate having a front surface, a back surface and a plurality of second through holes connecting the front surface and the back surface, and an adhesive layer joining the back surface of the front plate and the front surface of the back plate. The plurality of first through holes are aligned with the plurality of second through holes, and the front plate and the back plate are formed from dissimilar materials.

### CROSS-REFERENCE TO RELATED APPLICATIONS

This application claims priority to U.S. Provisional Patent Application Ser. No. 61/888,995, filed on Oct. 9, 2013, which herein is incorporated by reference.

### BACKGROUND

1. Field

Embodiments of the present disclosure generally relate to apparatus and methods for semiconductor processing. More particularly, embodiments of the present disclosure relate to apparatus and methods for delivering one or more processing gas in disassociated phase to a processing chamber.

2. Description of the Related Art

Disassociated processing gas is commonly used in semiconductor processing. Hollow cathode discharge plasma and electron beam sources are one of the common plasma sources for generating disassociated processing gas. Generally, a hollow cathode plasma source includes a cathode having an inner volume and a ground anode disposed apart from the cathode facing the inner volume. During operation, molecular gases are introduced to the inner volume of the cathode while a RF power is applied between the cathode and the ground electrode to create radicals from the molecular gas within the inner volume. After generation, the disassociated processing gas may be delivered to a processing chamber through a showerhead assembly attached to the hollow cathode plasma source.

Active species in the disassociated processing gas may recombine and form a deposition on the surfaces of the flow path, such as on surfaces of the showerhead, while being delivered to the processing chamber. The unintended deposition on the surfaces of showerhead may cause various problems, such as lowered efficiency and particle contamination. Conventionally, a showerhead may be cleaned using a cleaning chemistry in a regular basis to remove any unintended deposition. Showerheads, usually formed from metallic material, such as aluminum or stainless steel, are conventionally coated with a compatible coating to prevent any damages to the showerhead during cleaning. However, as demands for uniformity increases, openings in a showerhead become too small and/or too high aspect ratio to receive a coating and subject the showerhead either to damage from disassociated cleaning gas or unintended deposition from the disassociated processing gas.

Therefore, there is a need for improved showerhead for delivering processing gas in disassociated phase to a processing chamber.

### SUMMARY

Embodiments of the present disclosure generally relate to apparatus and methods for delivering disassociated processing gas to a processing chamber.

One embodiment of the present disclosure provides a showerhead assembly. The showerhead assembly includes a front plate having a front surface, a back surface and a plurality of first through holes connecting the front surface and the back surface and a back plate having a front surface, a back surface and a plurality of second through holes connecting the front surface and the back surface. The plurality of first through holes are smaller in diameter than the plurality of second through holes. The showerhead assembly further includes a protective coating formed on surfaces of the back plate, and an adhesive layer joining the back surface of the front plate and the front surface of the back plate. The plurality of first through holes are aligned with the plurality of second through holes, and the front plate and the back plate are formed from dissimilar materials.

Another embodiment of the present disclosure provides an apparatus for processing semiconductor substrate. The apparatus includes a chamber body defining an inner volume, a substrate support assembly disposed in the inner volume, a hollow cathode plasma source configured to provide one or more processing gas in disassociated phase to the inner volume, and a showerhead assembly disposed between the hollow cathode plasma source and the substrate support assembly to deliver disassociated processing gas from the hollow cathode plasma source to the inner volume. The showerhead assembly includes a front plate having a front surface, a back surface and a plurality of first through holes connecting the front surface and the back surface, wherein the front surface of the front plate faces the inner volume, a back plate having a front surface, a back surface and a plurality of second through holes connecting the front surface and the back surface, wherein the back surface of the back plate faces the hollow cathode plasma source, and an adhesive layer joining the back surface of the front plate and the front surface of the back plate, wherein the plurality of first through holes are aligned with the plurality of second through holes, and the front plate and the back plate are formed from dissimilar materials.

Another embodiment of the present disclosure provides a method for delivering processing gas in disassociated phase. The method includes generating disassociated processing gas within a plasma cavity of a hollow cathode plasma source, flowing the disassociated processing gas through a plurality of through holes in a back plate of a showerhead assembly, and flowing the disassociated processing gas through a plurality of through holes in a front plate of the showerhead assembly. A back surface of the front plate and a front surface of the back plate are joined by an adhesive layer, the plurality of through holes of the back plate are aligned with the plurality of through holes of the front plate, and the front plate and the back plate are formed from dissimilar materials.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic sectional view of a plasma processing chamber.

FIG. 2A is a schematic partial sectional view of a showerhead assembly.

FIG. 2B is a schematic partial top view of a gas distribution plate of the showerhead assembly of FIG. 2A.

FIG. 2C is an enlarged sectional view of a joint of a showerhead assembly of FIG. 2A.

FIG. 2D is a schematic top view of a fastener cap.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for delivering processing gas in disassociated phase to a processing environment. One embodiment provides a showerhead assembly having a front plate and a back plate joined together by an adhesive layer. The front plate and back plate may be formed from different materials. The front plate may be formed from a material compatible with cleaning gas in disassociated state and has a plurality of through holes small enough to satisfy processing requirements. The back plate may be formed from metallic material and has a plurality through holes large enough to receive a coating compatible with the processing gas. In one embedment, a clamping mechanism may be applied to the front plate and the back plate to ensure uniform contact between the front plate and back plate. The conductive back plate of the showerhead assembly may be coupled to an RF ground of the plasma source. The front plate may face the processing environment of the processing chamber and delivers disassociated processing gas through the plurality of small through holes. The showerhead assembly of the present disclosure is compatible with cleaning chemistry and including small through holes for gas delivery.

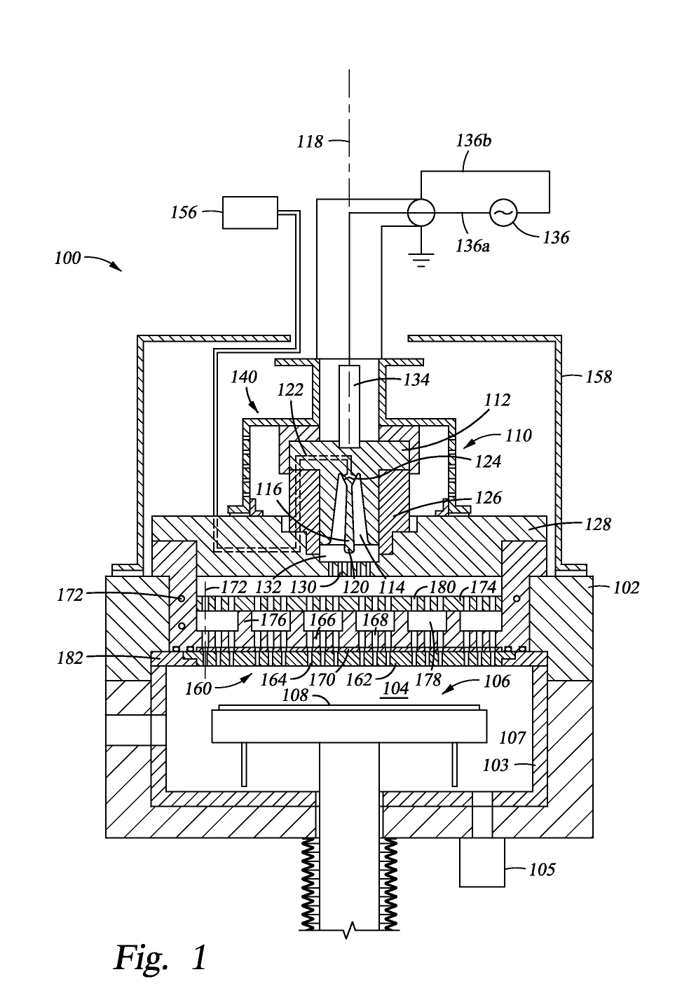

FIG. 1 is a schematic sectional view of a plasma processing chamber 100 according to one embodiment of the present disclosure. The plasma processing chamber 100 includes a showerhead assembly 160 according to embodiments of the present disclosure.

The plasma processing chamber 100 generally includes a chamber body 102 and a liner 103 disposed in inside the chamber body 102. The liner 103 defines a chamber volume 104 for substrate processing. A substrate support assembly 106 is disposed in the chamber volume 104 to support a substrate 108 to be processed. An exhaust port 107 may be formed through the chamber body 102 and connected with a vacuum pump 105 to maintain a low pressured process environment during operation.

The hollow cathode plasma source 110 is disposed above the chamber body 102 for supplying processing gas in disassociated phase and/or molecular phase to the chamber volume 104. The hollow cathode plasma source 110 includes a hollow cathode 112, a ground electrode 128 and an isolator 126 disposed between the hollow cathode 112 and the ground electrode 128.

The hollow cathode 112 may be formed from a RF conductive material and have an inner volume 114 which serves as plasma cavity during plasma generation. The hollow cathode 112 and the inner volume 114 may be symmetric about a central axis 118. A central rod 116, formed from a RF conductive material, is coupled to the hollow cathode 112. A lower end 120 of the central rod 116 extends along the central axis 118 out of the inner volume 114 towards the ground electrode 128. By extending out of the inner volume 114, the lower end 120 of the central rod 116 is the closest to the ground electrode 128 compared with other portions of the hollow cathode 112, as a result, plasma always ignites at the lower end of the central rod 116.

A gas channel 122 is formed in the hollow cathode 112 for delivering one or more processing gas from a gas source 156 to the inner volume 114 of the hollow cathode 112. The gas channel 122 includes a plurality of outlets 124 formed around the upper end 119 of the central rod 116. The plurality of outlets 124 may be evenly distributed about the central axis 118 and the central rod 116.

The ground electrode 128 may be a conductive plate having a recess 132 along the central axis 118 for receiving the isolator 126 and the hollow cathode 112. A plurality of through holes 130 may be formed through the ground electrode 128 to allow the plasma formed in the inner volume 114 to enter the chamber volume 104 for processing.

A RF connector 134 may be attached to the hollow cathode 112 on the upper side 112a. The RF connector 134 may be disposed along the central axis 118 to provide electrical symmetry with a central RF feed configuration. The RF connector 134 may be coupled to a RF output 136a of a RF power source 136 so that the hollow cathode 112 is RF hot during operation.

The plasma processing chamber 100 further includes a RF ground shield assembly 140 that encloses the hollow cathode 112 and the RF connector 134. During operation, a RF ground 136b of the RF power source 136 may be connected to the RF ground shield assembly 140.

An outer shell 158 may be disposed over the chamber body 102 to shield the hollow cathode plasma source 110 from any external noises, such as magnetic noises. In one embodiment, the outer shell 158 may be formed from a material having high magnetic permeability, such as mu-metal.

The showerhead assembly 160 is disposed between the hollow cathode plasma source 110 and the substrate support assembly 106. The showerhead assembly 160 may be used to uniformly distribute processing gas from the hollow cathode plasma source 110 to the chamber volume 104.

The showerhead assembly 160 includes a front plate 162 facing the chamber volume 104 and a back plate 166 attached to the front plate 162. The back plate 166 faces the hollow cathode plasma source 110 in a space apart relation. In one embodiment, the front plate 162 and the back plate 166 may be joined by an adhesive layer 170. A plurality of flow paths 172 may be formed through the front plate 162. In one embodiment, the plurality of flow paths 172 may be formed from a plurality of through holes 164 in the front plate 162 and the plurality of through holes 168 in the back plate 166. Each of the plurality of through holes 164 may align with a corresponding one of the plurality of through holes 168 to form one flow paths 172.

The plurality of through holes 164 on the front plate 162 may be smaller in diameter than the plurality of through holes 168 in the back plate 166 to create a restriction in each flow path 172. The restriction created by the smaller through holes 164 provides a back pressure for the processing gas passing through that facilitates even pressure distribution in a plenum 111 defined between the hollow cathode plasma source 110 and the showerhead assembly 160 which provides uniform gas flow towards and across the width of the substrate 108.

The adhesive layer 170 may be a perforated adhesive sheet having a plurality of openings 171 aligns with the through holes 164 and 168. The plurality of openings 171 are formed to allow precise alignment between the corresponding through holes 164 and 168, thus keep the through holes 164, 168 from clogging. Alternatively, the adhesive layer 170 may include a plurality of adhesive beads or adhesive rings. The adhesive layer 170 may be formed from an adhesive material having thermal conductive additives to ensure thermal exchange between the front plate 162 and the back plate 166. In one embodiment, the thermal conductive additive may be a metal powder.

In one embodiment, the back plate 166 includes a temperature control element 173 to main a target temperature in the showerhead assembly 160 during operation. The temperature control element 173 may include an embedded heating element and/or cooling channel for circulating a temperature control fluid therein. The temperature control element 173 may be used to maintain a desired temperature of the back plate 166 and the front plate 162 during processing. Formed from a thermal conductive material, the back plate 166 may respond to the temperature control element 173 quickly and reach uniform temperature in a timely manner. In one embodiment, the back plate 166 may have enough mass to act as a heat sink for the front plate 162 to maintain a desired temperature in the front plate 162.

The showerhead assembly 160 may also include a clamp ring 182 attached to the back plate 166. The clamp ring 182 may be disposed radially outside the front plate 162. In one embodiment, the clamp ring 182 and the front plate 162 may overlap to secure the front plate 162 on the back plate 166. The clamp ring 182 functions to facilitate secure and uniform contact between the front plate 162 and the back plate 166 across the showerhead assembly 160. By clamping the front plate 162 and the back plate 166 together, the clamp ring 182 enables consistent thermal conduct between the front plate 162 and the back plate 166 to prevent thermal non-uniformity in the front plate 162 caused by deterioration of the adhesive layer 170. The clamp ring 182 may be formed from a material compatible with the processing chemistry. In one embodiment, the clamp ring 182 may be formed from the same material as the liner 103, such as silicon carbide.

The showerhead assembly 160 may also include a blocker plate 174 disposed upstream to the back plate 166. The blocker plate 174 may be secured against a plurality of posts 176 extending from the back plate 166. A gas redistributing volume 178 is formed between the back plate 166 and the blocker plate 174. The blocker plate 174 may include a plurality of through holes 180 for directing processing gas from the hollow cathode plasma source 110 to the gas redistributing volume 178.

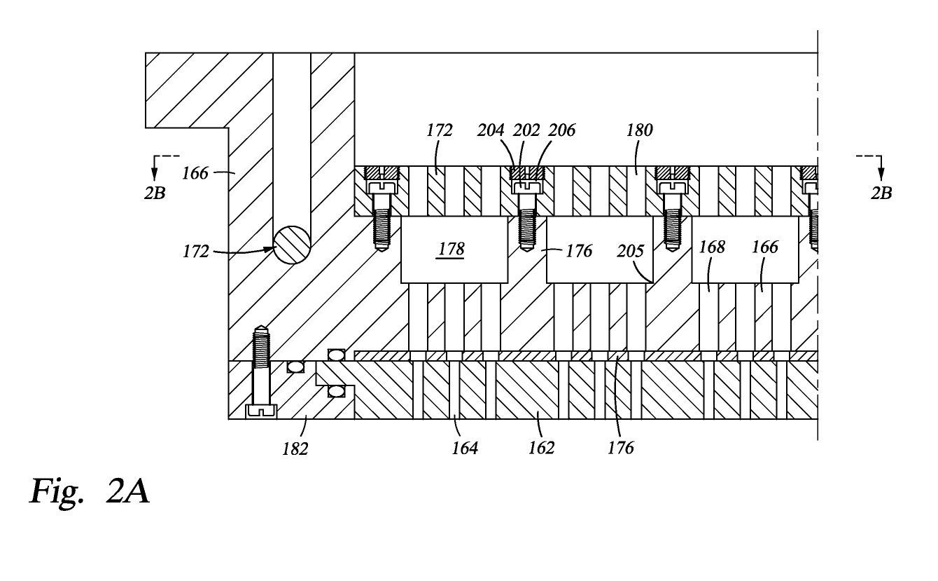

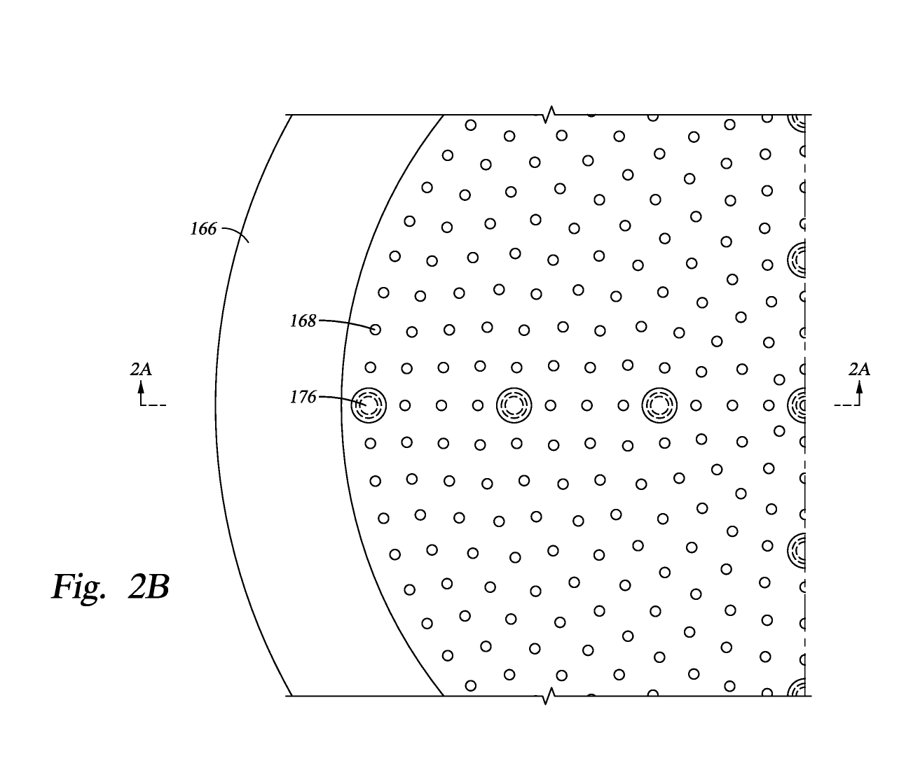

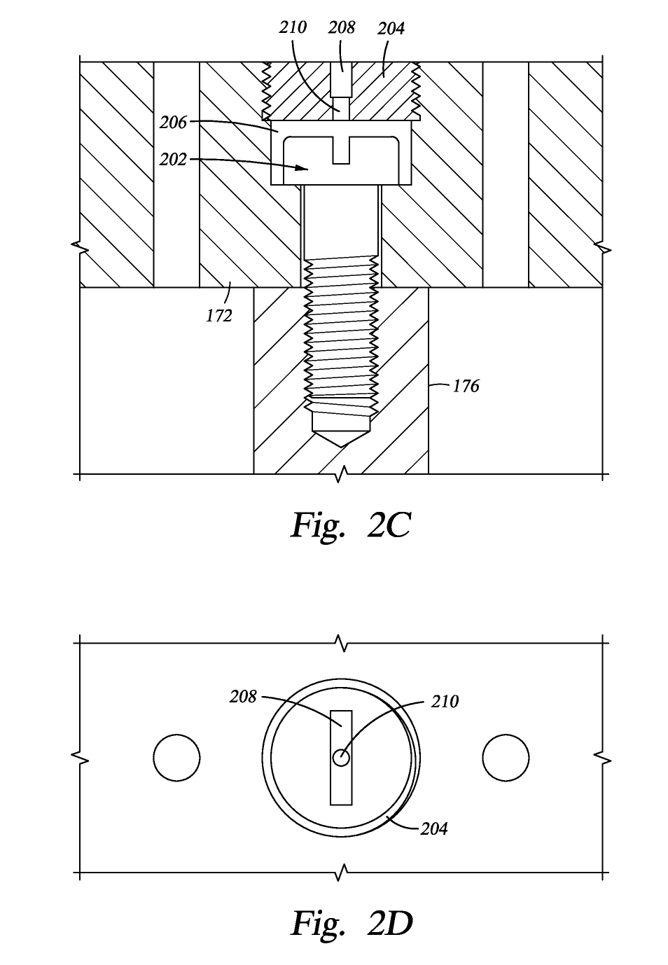

FIG. 2A is a schematic partial enlarged sectional view of the showerhead assembly 160 according to one embodiment of the present disclosure. The clamp ring 182 may be coupled to the back plate 166 by a plurality of fasteners 252 securing an edge 254 of the front plate 162 therebetween. The plurality of fasteners 252 may be evenly distributed along the clamping ring 182.

As discussed above, the back plate 166 may be formed from a thermal and/or electrical conductive material, such as a metal, so that the back plate 166 may be connected to the RF ground or RF source output and to facilitate temperature control during operation. In one embodiment, the back plate 166 is formed form aluminum. A protective coating 250 may be formed on surfaces, including interior surfaces of the plurality of through holes 168, to protect the metallic body of the back plate 166 from cleaning chemistry and/or processing chemistry. The plurality of through holes 168 may be large enough so that traditional coating formation methods, such as spray coating, may be used to form the protective coating 250 over the entire interior surfaces of the plurality of through holes 168. Similarly, a protective coating 256 of the same type may be formed on surfaces on the blocker plate 174. In one embodiment, the protective coatings 250, 256 may be formed from nickel, aluminum oxide, Yttria based coating or the like. In one embodiment, the protective coating may be a nickel film formed by electroless plating.

The front plate 162 may be formed from a material that is compatible to the processing chemistry and/or cleaning chemistry without using a protective coating. The front plate 162 may be formed from ceramic or semiconductor material without any coatings on surfaces. Particularly, no coatings are applied on surfaces defining the plurality of through holes 164. In one embodiment, the front plate 162 may be formed from silicon to be compatible with etch/clean chemistry. For example, the processing chemistry may be a processing gas including NH₃ and NF₃ for performing etch or chamber cleaning. During processing, the processing gas including NH₃ and NF₃ may be disassociated in the hollow cathode plasma source 110 and the disassociated processing gas passes through the showerhead assembly 160 to remove native oxide from surfaces of the chamber components or from a substrate being processed.

The material choice of the front plate 162 enables the through holes 164 to be small in diameter to achieve desired flow conductance. The through holes 164 of the front plate 162 may have a diameter between about 0.020 inch and about 0.040 inch or a length/diameter aspect ratio between about 21.7 and about 10.85. Prior to applying the protective coating 250, the through holes 168 of the back plate 166 may have a diameter between about 0.089 inch and about 0.099 inch or a length/diameter aspect ratio between about 1.90 and about 2.11. Thickness of the protective coatings 250, 256 may determine the lifetime of the back plate 166 and the blocker plate 174. The thicker the coating, the longer the lifetime. The showerhead assembly 160 with smaller through holes 164 in the front plate 162 allows the back plate 166 and the blocker plate 174 to have through holes components, thus thicker coatings which lead to longer lifetime. In one embodiment, the protective coatings 250, 256 may have a thickness between about 0.0010 inch and about 0.0012 inch.

The blocker plate 174 may be attached to one or more of the plurality of posts 176 by a plurality of fasteners 202. The blocker plate 174 may include a plurality of recess 206 for receiving the plurality of fasteners 202. A cap 204 may cover each of the plurality of recesses 206. In one embodiment, the protective coating 256 may be applied over the cap 204.

The posts 176 may extend from the back plate 166 through rounded corners 205 to enhance fluid flow in the gas redistributing volume 178. In one embodiment, the posts 176 may include rounded corners 258 for to avoid plasma arcing, avoid gas/particle traps, and reduce mechanical stress. The concentration and distribution of the posts 176 may be arranged to provide uniform thermal exchange between the blocker plate 174 and the back plate 166. FIG. 2B is a schematic partial top view of the back plate 166 showing the distribution of the posts 176 according to one embodiment of the present disclosure. In the embodiment where the hollow cathode plasma source 110 includes multiple cathodes, concentric walls 212 (shown in ghost lines in FIG. 2A) may extend from the back plate 166 to the blocker plate 174 to form concentrically isolated zones around one or more hollow cathode plasma sources 110 in the gas redistributing volume 178.

FIG. 2C is an enlarged sectional view of the fastener 202 and cap 204. The cap 204 may be secured to the blocker plate 174 by threads. A notch 208 may be formed on the cap 204 to enable fastening and loosening. A vent hole 210 may be formed through the cap 204 to allow equal pressure on opposite sides of the cap 204. FIG. 2D is a schematic top view of the cap 204 showing the notch 208 and the vent hole 210.

The showerhead assembly of the present disclosure may be used to any suitable processes. In one embodiment, the showerhead assembly may be used to perform a dry etch process for removing silicon oxide using an ammonia (NH₃) and nitrogen trifluoride (NF₃) gas mixture.

While the foregoing is directed to embodiments of the present disclosure, other and further embodiments of the disclosure may be devised without departing from the basic scope thereof, and the scope thereof is determined by the claims that follow.

We claim:

1. A showerhead assembly, comprising:
a front plate having a front surface, a back surface and a plurality of first through holes connecting the front surface and the back surface;
a back plate having a front surface, a back surface and a plurality of second through holes connecting the front surface and the back surface, wherein the plurality of first through holes are smaller in diameter than the plurality of second through holes;
a protective coating is formed on surfaces of the back plate; and
an adhesive layer joining the back surface of the front plate and the front surface of the back plate, wherein the plurality of first through holes are aligned with the plurality of second through holes, and the front plate and the back plate are formed from dissimilar materials.

2. The showerhead assembly of claim 1, wherein the back plate is formed from a metallic material and adapted to couple with a RF power source, and the front plate is formed from a non-metallic material and adapted to face a processing environment with the front surface.

3. The showerhead assembly of claim 2, wherein the front plate is formed from a semiconductor material.

4. The showerhead assembly of claim 1, further comprising a blocker plate attached to the back plate.

5. The showerhead assembly of claim 1, wherein the back plate has a plurality of posts extending from the back surface and are contacting the blocker plate.

6. The showerhead assembly of claim 5, wherein the back plate has one or more concentric walls extending from the back surface, and the one or more concentric walls dividing the back plate to two or more isolated regions.

7. The showerhead assembly of claim 5, further comprising a plurality of fasteners securing the blocker plate to the plurality of posts of the back plate.

8. The showerhead assembly of claim 7, further comprising a plurality of caps covering the plurality of fasteners.

9. The showerhead assembly of claim 1, further comprising a clamp ring attached to the front surface of the back plate, wherein an inner diameter of the clamp ring overlaps with an outer diameter of the front plate so that the clamp ring holds the front plate against the back plate.

10. An apparatus for processing semiconductor substrate, comprising:
a chamber body defining an inner volume;
a substrate support assembly disposed in the inner volume;
a hollow cathode plasma source configured to provide one or more processing gas in disassociated phase to the inner volume; and
a showerhead assembly disposed between the hollow cathode plasma source and the substrate support assembly to deliver disassociated processing gas from the hollow cathode plasma source to the inner volume, wherein the showerhead assembly comprises:
a front plate having a front surface, a back surface and a plurality of first through holes connecting the front surface and the back surface, wherein the front surface of the front plate faces the inner volume;
a back plate having a front surface, a back surface and a plurality of second through holes connecting the front surface and the back surface, wherein the back surface of the back plate faces the hollow cathode plasma source, and the plurality of first through holes are smaller in diameter than the plurality of second through holes;
a protective coating is formed on surfaces of the back plate; and
an adhesive layer joining the back surface of the front plate and the front surface of the back plate, wherein the plurality of first through holes are aligned with the plurality of second through holes, and the front plate and the back plate are formed from dissimilar materials.

11. The apparatus of claim 10, wherein the back plate of the showerhead assembly is formed from a metallic material and electrically coupled with a ground electrode of the hollow cathode plasma source.

12. The apparatus of claim 11, wherein the front plate is formed from a non-metallic material.

13. The apparatus of claim 12, wherein the front plate is formed from silicon.

14. The apparatus of claim 10, wherein the showerhead assembly further comprises a blocker plate attached to the back plate.

15. The apparatus of claim 14, wherein the showerhead assembly further comprises a plurality of fasteners securing the blocker plate to the back plate.

16. The apparatus of claim 15, wherein the showerhead assembly has a plurality of posts extending from the back surface of the back plate and spacing the back plate from the blocker plate.

17. The apparatus of claim 10, wherein the hollow cathode plasma source comprises multiple independently controlled hollow cathodes, the showerhead assembly has one or more concentric walls extending from the back surface of the back plate, and the one or more concentric walls dividing the showerhead assembly to two or more isolated regions.

18. The apparatus of claim 10, wherein the showerhead assembly further comprises a clamp ring attached to the front surface of the back plate, wherein an inner diameter of the clamp ring overlaps with an outer diameter of the front plate so that the clamp ring holds the front plate against the back plate.

19. A method for delivering processing gas in disassociated phase, comprising:
generating a plasma within a plasma cavity of a hollow cathode plasma source to disassociate a processing gas;
flowing the disassociated processing gas through a plurality of first through holes in a back plate of a showerhead assembly, wherein a protective coating is formed on surfaces of the back plate; and
flowing the disassociated processing gas through a plurality of second through holes in a front plate of the showerhead assembly, wherein a back surface of the front plate and a front surface of the back plate are joined by an adhesive layer, the plurality of through holes of the back plate are larger in diameter than and are aligned with the plurality of through holes of the front plate, and the front plate and the back plate are formed from dissimilar materials.

20. The method of claim 19, further comprising flowing the disassociated processing gas through a blocker plate prior to flowing the disassociated processing gas through the back plate.
